(19) United States
(12) Patent Application Publication
(10) Pub. No.: US 2022/0110210 A1
(43) Pub. Date: Apr. 7, 2022

(54) COIL SUBSTRATE, MOTOR COIL SUBSTRATE, AND MOTOR

(71) Applicant: IBIDEN CO., LTD., Ogaki (JP)

(72) Inventors: Haruhiko MORITA, Ogaki (JP); Hitoshi MIWA, Ogaki (JP); Shinobu KATO, Ogaki (JP); Toshihiko YOKOMAKU, Ogaki (JP); Hisashi KATO, Ogaki (JP); Takahisa HIRASAWA, Ogaki (JP); Tetsuya MURAKI, Ogaki (JP); Takayuki FURUNO, Ogaki (JP)

(73) Assignee: IBIDEN CO., LTD., Ogaki (JP)

(21) Appl. No.: 17/488,769

(22) Filed: Sep. 29, 2021

(30) Foreign Application Priority Data
Oct. 7, 2020 (JP) 2020-169904

(51) Int. Cl. H05K 1/02; H02K 3/04; H05K 1/18

(52) U.S. Cl. CPC H05K 1/0277; H05K 2201/1009; H05K 1/189; H02K 3/04

(57) ABSTRACT

A coil substrate includes a first flexible substrate, a coil formed on the first flexible substrate, a second flexible substrate extending from the first flexible substrate, and a wiring that is formed on the second flexible substrate and is electrically connected to the coil formed on the first flexible substrate. The second flexible substrate includes a first portion extending from the first flexible substrate and a second portion extending from the first portion such that the second portion is formed along the first flexible substrate and that the second flexible substrate forms a gap between the second portion and the first flexible substrate.

### CROSS-REFERENCE TO RELATED APPLICATIONS

The present application is based upon and claims the benefit of priority to Japanese Patent Application No. 2020-169904, filed Oct. 7, 2020, the entire contents of which are incorporated herein by reference.

### BACKGROUND OF THE INVENTION

### Field of the Invention

The present invention relates to a coil substrate, a motor coil substrate, and a motor.

### Description of Background Art

Japanese Patent Application Laid-Open Publication No. H6-105493 describes a coreless coil. The entire contents of this publication are incorporated herein by reference.

### SUMMARY OF THE INVENTION

According to one aspect of the present invention, a coil substrate includes a first flexible substrate, a coil formed on the first flexible substrate, a second flexible substrate extending from the first flexible substrate, and a wiring that is formed on the second flexible substrate and is electrically connected to the coil formed on the first flexible substrate. The second flexible substrate includes a first portion extending from the first flexible substrate and a second portion extending from the first portion such that the second portion is formed along the first flexible substrate and that the second flexible substrate forms a gap between the second portion and the first flexible substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a schematic diagram of a motor according to an embodiment of the present invention;

FIG. 1B is a schematic diagram of a motor coil substrate according to an embodiment of the present invention;

FIG. 1C is a plan view of a coil according to an embodiment of the present invention;

FIG. 1D illustrates a portion of a second flexible substrate according to an embodiment of the present invention;

FIG. 2A is a schematic diagram of a motor coil substrate according to an embodiment of the present invention;

FIGS. 2B and 2C are schematic diagrams illustrating how a second flexible substrate is folded according to an embodiment of the present invention;

FIG. 3 is a plan view of a printed wiring board for manufacturing coil substrates according to an embodiment of the present invention; and

FIG. 4 is a plan view of a printed wiring board for manufacturing coil substrates of a reference example.

### DETAILED DESCRIPTION OF THE EMBODIMENTS

Embodiments will now be described with reference to the accompanying drawings, wherein like reference numerals designate corresponding or identical elements throughout the various drawings.

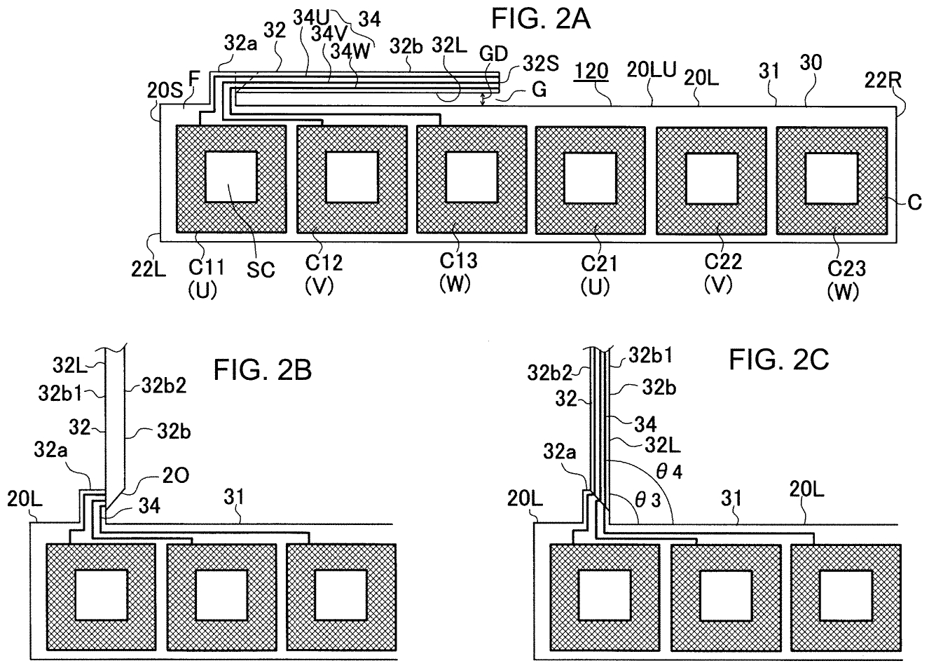

A coil substrate 120 illustrated in FIG. 2A is prepared. The coil substrate 120 is formed of: a flexible substrate 30 having a first surface (F) and a second surface (S) on the opposite side with respect to the first surface (F); coils (C) (C11, C12, C13, C21, C22, C23) formed on the first surface (F) of the flexible substrate 30; and wirings 34. The coils on the first surface (F) are referred to as on-first-surface coils. The coil substrate 120 can have coils (C) on the second surface (S). The coils on the second surface (S) are referred to as on-second-surface coils.

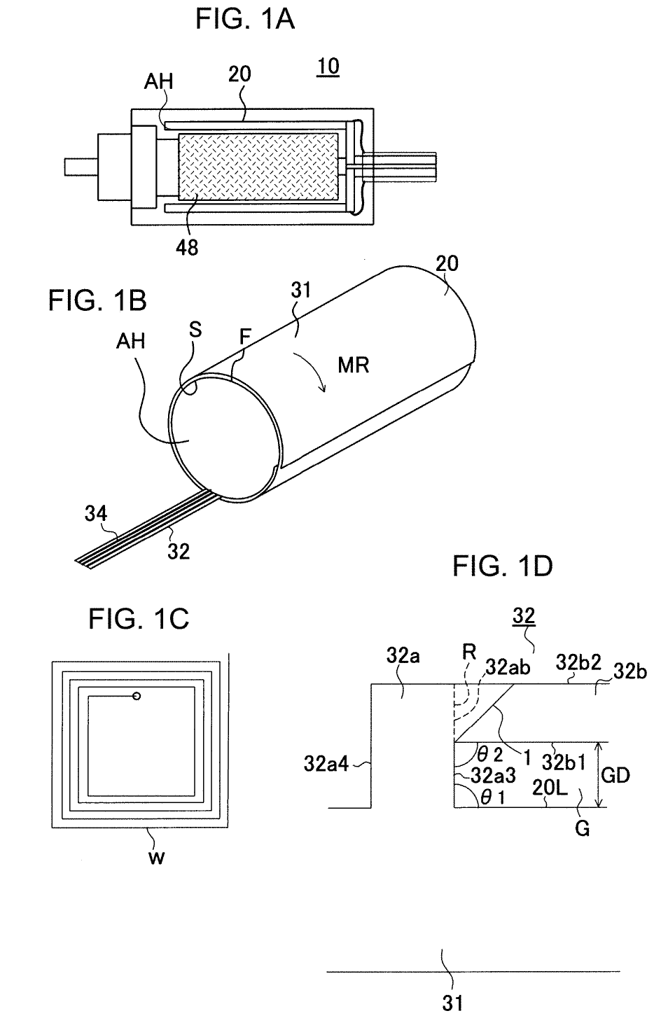

An example of wirings (w) forming a coil (C) is drawn in FIG. 1C. As illustrated in FIG. 1C, the wirings (w) are formed in a spiral shape. In FIGS. 2A-2C, 3, and 4, coils (C) are schematically drawn. In these drawings, the wirings (w) are grouped.

By winding the coil substrate 120, a motor coil substrate 20 illustrated in FIG. 1B is obtained. For example, the coil substrate 120 is wound in a tubular shape. The motor coil substrate 20 is wound around a hollow space (AH). For example, the motor coil substrate 20 has a tubular shape. The number of windings (N) is 2 or more and 5 or less. FIG. 1B is a schematic diagram.

As illustrated in FIG. 1A, a motor 10 is obtained by positioning a magnet 48 inside the motor coil substrate 20. FIG. 1A is a schematic diagram. The motor coil substrate 20 is positioned around the magnet 48 via the hollow space (AH). An example of the motor 10 is a brushless motor. In the embodiment, the magnet 48 rotates. However, it is also possible that the motor coil substrate 20 rotates. A rotation direction (MR) of the motor 10 is illustrated in FIG. 1B.

As illustrated in FIG. 2A, the flexible substrate 30 is formed of a first flexible substrate 31 and a second flexible substrate 32. The first flexible substrate 31 and the second flexible substrate 32 are formed of a single flexible substrate 30. The flexible substrate 30, the first flexible substrate 31, and the second flexible substrate 32 each have a substantially rectangular planar shape. The coils (C) are formed on the first flexible substrate 31. The wirings 34 connected to the coils (C) are formed on the second flexible substrate 32. Currents are supplied to the coils (C) via the wirings 34.

The first flexible substrate 31 has short sides (first short sides) (20S) and long sides (first long sides) (20L). The first long side (20L) close to the second flexible substrate 32 is a fifth side (20LU). The first flexible substrate 31 has one end (22L) and the other end (22R) on the opposite side with respect to the one end (22L). One of the short sides (20S) also serves as the one end (22L). The coils (C) (C11, C12, C13, C21, C22, C23) are formed along the long sides (20L) of the first flexible substrate 31. The coils (C) are positioned in one row from the one end (22L) to the other end (22R) of the first flexible substrate 31. The coils (C) include U-phase coils (U), V-phase coils (V), and W-phase coils (W). The U-phase coils (U), the V-phase coils (V), and the W-phase coils (W) are formed in an order of a U-phase coil (U), a V-phase coil (V), and a W-phase coil (W), and the coil (C) closest to the one end (22L) is a U-phase coil (U). The number of the coils (C) is a multiple (M) (number (M)) of 3. In the example of FIG. 2A, the number of the coils is 6.

The second flexible substrate 32 extends from the first flexible substrate 31. The second flexible substrate 32 is formed of a first portion (32a) that extends from the first flexible substrate 31 and a second portion (32b) that extends from the first portion (32a). The second portion (32b) is formed along the first long sides (20L) of the first flexible substrate 31. The second portion (32b) is formed along the fifth side (20LU). The second portion (32b) has a substantially rectangular shape having long sides (second long sides) (32L) and short sides (second short sides) (32S). The first long sides (20L) and the second long sides (32L) face each other. The fifth side (20LU) and the second long sides (32L) face each other. The first flexible substrate 31, the first portion (32a) and the second portion (32b) are formed of the single flexible substrate 30.

FIG. 1D illustrates a portion of the second flexible substrate 32. A boundary (R) between the first portion (32a) and the second portion (32b) is drawn using a dotted line (32ab). The second portion (32b) has a side (first side) (32b1) facing the first flexible substrate and a second side (32b2) on the opposite side with respect to the first side (32b1). The first portion (32a) has a third side (32a3) connected to the first side (32b1) and a fourth side (32a4) on the opposite side with respect to the third side (32a3). The fourth side (32a4) is connected to the second side (32b2).

The second flexible substrate 32 is bent substantially at a right angle between the first portion (32a) and the second portion (32b). An angle (Θ1) between the first long side (20L) and the first portion (32a) is substantially 90 degrees. The angle (Θ1) between the first long side (20L) and the third side (32a3) is substantially 90 degrees. An angle (Θ2) between the second portion (32b) and the first portion (32a) is substantially 90 degrees.

The angle (Θ2) between the first side (32b1) and the third side (32a3) is substantially 90 degrees. The angle (Θ1) and the angle (Θ2) are illustrated in FIG. 1D.

A gap (G) is formed between the second portion (32b) and the first flexible substrate 31. The gap (G) has a substantially uniform width (GD). The width (GD) is a distance between the fifth side (20LU) and the first side (32b1). The gap (G) and the width (GD) are illustrated in FIGS. 1D and 2A.

Currents are supplied to the coils (C) via the wirings 34 formed on the second flexible substrate 32. The wirings 34 include U-phase wirings (34U) for supplying power to the U-phase coils (U), V-phase wirings (34V) for supplying power to the V-phase coils (V), and W-phase wirings (34W) for supplying power to the W-phase coils (W).

As illustrated in FIGS. 2B and 2C, the second flexible substrate 32 is folded. By the folding, orientation of the second flexible substrate 32 is changed. Orientation of the wirings 34 is changed. As illustrated in FIG. 2C, the second flexible substrate 32 is folded such that an angle (Θ3) between the first long side (20L) and the second long side (32L) is substantially 90 degrees. The second flexible substrate 32 is folded such that an angle (Θ4) between the wirings 34 and the first long side (20L) is substantially 90 degrees. The angle (Θ3) and the angle (Θ4) are illustrated in FIG. 2C. For example, the number of folds of the second flexible substrate 32 is 2.

First, as illustrated in FIG. 2B, the second flexible substrate 32 is folded such that the third side (32a3) and the first side (32b1) are substantially parallel to each other. For example, the second flexible substrate 32 is folded along a line 1 in FIG. 1D. The first surface (F) and the first surface (F) face each other. The line 1 includes an intersection point of the third side (32a3) and the first side (32b1). The first side (32b1) is preferably positioned on an extension line of the third side (32a3). Subsequently, as illustrated in FIG. 2C, the second flexible substrate 32 is folded along the boundary (R). As a result, the third side (32a3) and the first side (32b1) are substantially parallel to each other. Further, a distance between the second side (32b2) and the fourth side (32a4) is reduced. The first side (32b1) is preferably positioned on an extension line of the third side (32a3). The second side (32b2) is preferably positioned on an extension line of the fourth side (32a4). The angle (Θ3) between the fifth side (20LU) and the first side (32b1) is substantially 90 degrees. The angle (Θ4) between the fifth side (20LU) and the wirings 34 is substantially 90 degrees. As a result, the second flexible substrate 32 extends substantially perpendicular to the first long side (20L) of the first flexible substrate 31.

The second flexible substrate 32 is folded. The folded portion includes an inner side and an outer side (2O). The outer side (2O) is illustrated in FIG. 2B. When the second flexible substrate 32 is folded such that the wirings 34 are formed on the outer side (2O), the wirings 34 are pulled. In this case, disconnection of the wirings 34 may occur. In the embodiment, the second flexible substrate 32 is folded such that the wirings 34 are formed on the inner side. Therefore, disconnection of the wirings 34 can be prevented.

By winding the coil substrate 120, the motor coil substrate 20 illustrated in FIG. 1B is formed. The second flexible substrate 32 extends substantially perpendicular to the rotation direction (MR) of the motor 10. The second flexible substrate 32 extends substantially perpendicular to the first long side (20L). The second flexible substrate 32 extends substantially perpendicular to the fifth side (20LU).

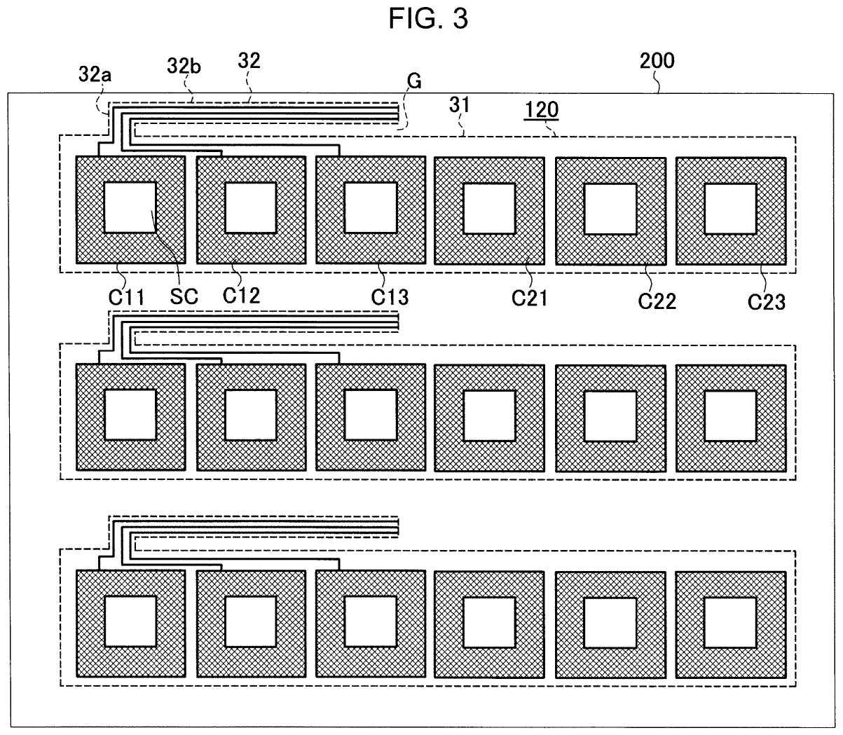

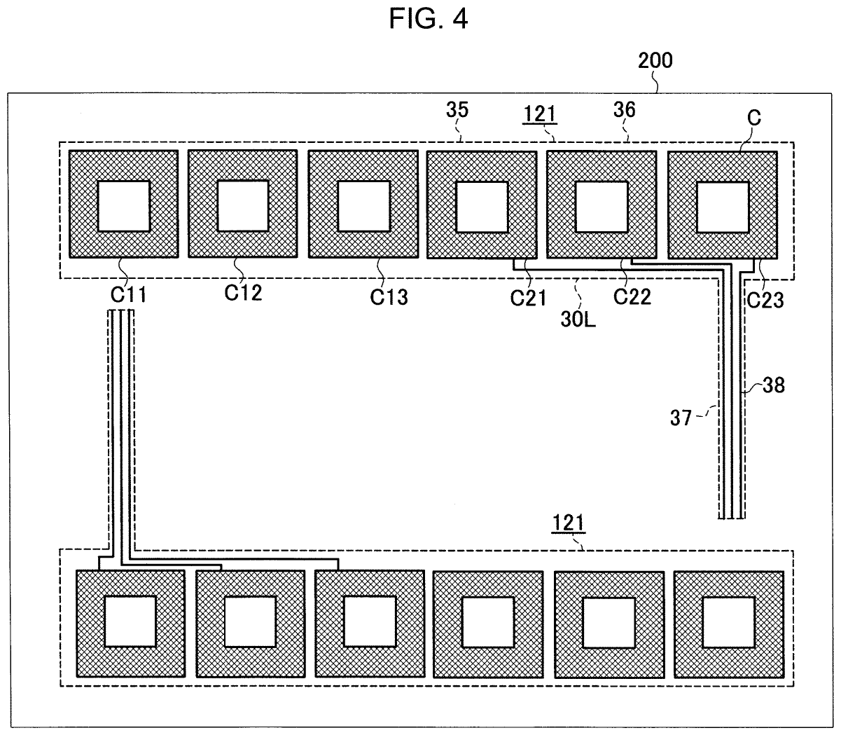

FIGS. 3 and 4 each illustrate a printed wiring board 200 for manufacturing coil substrates. FIG. 3 illustrates a printed wiring board 200 of the embodiment. FIG. 4 illustrates a printed wiring board 200 of a reference example.

The coil substrates in FIG. 3 are each a coil substrate 120 of the embodiment, and the coil substrates in FIG. 4 are each a coil substrate 121 of the reference example. A flexible substrate 35 forming the coil substrate 121 of the reference example is also formed of a first flexible substrate 36 and a second flexible substrate 37. The first flexible substrate 36 of the reference example also has a first long side (30L). The reference example also has coils (C) on the first flexible substrate 36 and wirings 38 on the second flexible substrate 37. And, in the reference example, the second flexible substrate 37 extends perpendicular to the first long side (30L).

As illustrated in FIGS. 3 and 4, in each of the embodiment and the reference example, multiple coil substrates (120, 121) are manufactured from the one printed wiring board 200. The printed wiring boards 200 illustrated in FIGS. 3 and 4 have the same size. The first flexible substrate 31 of the embodiment and the first flexible substrate 36 of the reference example have the same size. The second flexible substrate 32 of the embodiment and the second flexible substrate 37 of the reference example have the same size. The second flexible substrate 32 of the embodiment and the second flexible substrate 37 of the reference example have the same width. The second flexible substrate 32 of the embodiment and the second flexible substrate 37 of the reference example have the same length. The coil substrates (120, 121) of the embodiment and the reference example are different in planar shape. Therefore, in the embodiment, the number of the coil substrates 120 obtained from the one printed wiring board 200 is 3. In contrast, in the reference example, the number of the coil substrates 121 obtained from the one printed wiring board 200 is 2. In the embodiment, a large portion (the second portion (32b)) of the second flexible substrate 32 is formed along the first flexible substrate 31. Therefore, the number of the coil substrates 120 obtained from the one printed wiring board 200 can be increased.

By winding the coil substrate 120, the motor coil substrate 20 of the embodiment illustrated in FIG. 1B is obtained. As illustrated in FIG. 1B, the second flexible substrate 32 extends substantially perpendicular to the rotation direction (MR) of the motor. The wirings 34 extend substantially perpendicular to the rotation direction (MR) of the motor. Currents can be supplied to the coils (C) in the motor coil substrate 20 via the wirings 34. The coils (C) in the motor coil substrate 20 and a power supply can be easily connected.

In the printed wiring board industry, multiple products may be manufactured from one substrate. According to FIG. 3 of Japanese Patent Application Laid-Open Publication No. H6-105493, a lead part 18 extends vertically from an FPC 12. Therefore, it is considered that, according to the technology of Japanese Patent Application Laid-Open Publication No. H6-105493, it is difficult to increase the number of products manufactured from one substrate.

A coil substrate according to an embodiment of the present invention includes: a first flexible substrate; a coil that is formed on the first flexible substrate; a second flexible substrate that extends from the first flexible substrate; and a wiring that is formed on the second flexible substrate and is electrically connected to the coil. The second flexible substrate is formed of a first portion that extends from the first flexible substrate and a second portion that extends from the first portion. The second portion is formed along the first flexible substrate. A gap is formed between the second portion and the first flexible substrate.

According to an embodiment of the present invention, the second flexible substrate is formed of the first portion that extends from the first flexible substrate and a second portion that extends from the first portion. And, the second portion is formed along the first flexible substrate. Therefore, the coil substrate formed of the first flexible substrate and the second flexible substrate has a substantially rectangular planar shape. Therefore, according to the embodiment, multiple coil substrates can be efficiently formed on one substrate. The number of products manufactured from one substrate can be increased.

Obviously, numerous modifications and variations of the present invention are possible in light of the above teachings. It is therefore to be understood that within the scope of the appended claims, the invention may be practiced otherwise than as specifically described herein.

What is claimed is:

1. A coil substrate, comprising:
a first flexible substrate;
a coil formed on the first flexible substrate;
a second flexible substrate extending from the first flexible substrate; and
a wiring formed on the second flexible substrate and configured to be electrically connected to the coil formed on the first flexible substrate,
wherein the second flexible substrate includes a first portion extending from the first flexible substrate and a second portion extending from the first portion such that the second portion is formed along the first flexible substrate and that the second flexible substrate forms a gap between the second portion and the first flexible substrate.

2. The coil substrate according to claim 1, wherein the first flexible substrate has a substantially rectangular shape having a long side and a short side such that the second portion of the second flexible substrate is formed along the long side of the first flexible substrate.

3. The coil substrate according to claim 2, wherein the second portion of the second flexible substrate has a substantially rectangular shape having a long side and a short side such that the long side of the second portion in the second flexible substrate faces the long side of the first flexible substrate.

4. The coil substrate according to claim 1, wherein the second flexible substrate is formed such that the gap between the first flexible substrate and the second portion of the second flexible substrate has a substantially uniform width.

5. The coil substrate according to claim 1, wherein the first flexible substrate and the second substrate are formed such that a single flexible substrate has a first portion comprising the first flexible substrate and a second portion comprising the first and second portions of the second flexible substrate and that the second flexible substrate is configured to be bent between the first portion and the second portion.

6. The coil substrate according to claim 1, wherein the wiring formed on the second flexible substrate is configured to supply current to the coil formed on the first flexible substrate.

7. A motor coil substrate, comprising:
the coil substrate of claim 1 comprising the first flexible substrate that is wound and the second flexible substrate that is folded.

8. The motor coil substrate according to claim 7, wherein the second flexible substrate is folded twice.

9. The motor coil substrate according to claim 7, wherein the first flexible substrate has a substantially rectangular shape having a long side and a short side such that the second portion of the second flexible substrate is formed along the long side of the first flexible substrate and that when folded, the second flexible substrate is configured to extend substantially perpendicular to the long side of the first flexible substrate.

10. A motor, comprising:
the motor coil substrate of claim 7 having a space; and
a magnet positioned inside the space formed by the motor coil substrate,
wherein the motor coil substrate is formed such that the second flexible substrate extends substantially perpendicular to a rotation direction of the motor.

11. The motor according to claim 10, wherein the coil substrate is formed such that the second flexible substrate is configured to extend substantially perpendicular to a rotation direction of the motor when folded.

12. The coil substrate according to claim 2, wherein the second flexible substrate is formed such that the gap between the first flexible substrate and the second portion of the second flexible substrate has a substantially uniform width.

13. The coil substrate according to claim 2, wherein the first flexible substrate and the second substrate are formed such that a single flexible substrate has a first portion comprising includes the first flexible substrate and a second portion comprising the first and second portions of the second flexible substrate and that the second flexible substrate is configured to be bent between the first portion and the second portion.

14. The coil substrate according to claim 2, wherein the wiring formed on the second flexible substrate is configured to supply current to the coil formed on the first flexible substrate.

15. The coil substrate according to claim 3, wherein the second flexible substrate is formed such that the gap between the first flexible substrate and the second portion of the second flexible substrate has a substantially uniform width.

16. The coil substrate according to claim 3, wherein the first flexible substrate and the second substrate are formed such that a single flexible substrate has a first portion comprising includes the first flexible substrate and a second portion comprising the first and second portions of the second flexible substrate and that the second flexible substrate is 1 to be bent between the first portion and the second portion.

17. The coil substrate according to claim 3, wherein the wiring formed on the second flexible substrate is configured to supply current to the coil formed on the first flexible substrate.

18. The coil substrate according to claim 4, wherein the first flexible substrate and the second substrate are formed such that a single flexible substrate has a first portion comprising includes the first flexible substrate and a second portion comprising the first and second portions of the second flexible substrate and that the second flexible substrate is configured to be bent between the first portion and the second portion.

19. The coil substrate according to claim 4, wherein the wiring formed on the second flexible substrate is configured to supply current to the coil formed on the first flexible substrate.

20. The coil substrate according to claim 5, wherein the wiring formed on the second flexible substrate is configured to supply current to the coil formed on the first flexible substrate.
